(19) United States
(12) Patent Application Publication
(10) Pub. No.: US 2007/0007664 A1
(43) Pub. Date: Jan. 11, 2007

(54) SEMICONDUCTOR PACKAGE WITH MOLDED BACK SIDE AND METHOD OF FABRICATING THE SAME

(76) Inventors: Chung-Sun LEE, Gyeonggi-do (KR); Yong-Hwan KWON, Gyeonggi-do (KR); Kyoung-Sei CHOI, Chungcheongnam-do (KR); Woon-Byung KANG, Gyeonggi-do (KR)

Correspondence Address: MARGER JOHNSON & MCCOLLOM, P.C., 210 SW MORRISON STREET, SUITE 400, PORTLAND, OR, 97204, US

(21) Appl. No.: 11/428,169

(22) Filed: Jun. 30, 2006

(30) Foreign Application Priority Data
Jul. 6, 2005 (KR) 10-2005-0060788

(51) Int. Cl. H01L 23/48; H01L 21/00; H01L 21/44

(52) U.S. Cl. 257/779; 257/773; 438/113; 438/612

(57) ABSTRACT

Provided are a semiconductor package having a semiconductor chip, a rear surface of which is molded, and a method of fabricating the semiconductor package. The semiconductor package includes a semiconductor chip including a wafer and a metal pad formed on a front surface of the wafer; a solder ball formed on a front surface of the wafer, and electrically connected to the metal pad; and a reinforcing member formed on a rear surface of the wafer. The reinforcing member is formed of an epoxy molding compound, and the reinforcing member protrudes at least 5 μm from side surfaces of the semiconductor chip.

### CROSS-REFERENCE TO RELATED PATENT APPLICATIONS

This application claims the benefit of Korean Patent Application No. 10-2005-0060788, filed on Jul. 6, 2005, in the Korean Intellectual Property Office, the disclosure of which is incorporated herein in its entirety by reference.

### BACKGROUND OF THE INVENTION

1. Field of the Invention

The present invention relates to a semiconductor package, and more particularly, to a wafer level package having a molded back surface and a method of fabricating the package.

2. Description of the Related Art

Semiconductor packages electrically connect inputs/outputs of a semiconductor chip to other devices and protect the semiconductor chip. As electronic devices become smaller, lighter, and more highly functional, semiconductor packages that are small, light, economical, and highly reliable are required. Wafer level packages, in which assemblies of semiconductor chips and packages can be produced at wafer level, have been developed. In wafer level packages, all semiconductor chips on the wafer are processed and assembled, and thus, fabrication costs of the semiconductor device can be reduced greatly. In addition, performances of the package and performances of the semiconductor chip can be cooperated completely, thermal and electrical properties of the semiconductor device can be improved, and the package size can be reduced to a size of the semiconductor chip.

FIG. 1 is a cross-sectional view of a conventional wafer level package 100. Referring to FIG. 1, a metal pad 120 is formed on a front surface 111 of a wafer 110. A metal wiring layer 150 is electrically connected to the metal pad 120, and is also electrically connected to a solder ball 170. A first insulating layer 130 and a second insulating layer 140 are formed between the metal pad 120 and the metal wiring layer 150, and a third insulating layer 160 is formed on the metal wiring layer 150. The first through third insulating layers 130, 140, and 160 respectively include openings 135, 145, and 165. According to the conventional wafer level package 100, a rear surface 112 of the wafer 110 is exposed, and thus, the conventional wafer level package 100 is weak against external shock, and edge clipping may occur.

Therefore, a wafer level package having a rear surface, on which a coating layer is formed, has been suggested. Referring to FIG. 2, a metal pad 220, a metal wiring layer 250 connected to the metal pad 220, and a solder ball 270 electrically connected to the metal wiring layer 250 are formed on a front surface 211 of the wafer 210. A first insulating layer 230 and a second insulating layer 240 are formed between the metal pad 220 and the metal wiring layer 250, and a third insulating layer 260 is formed on the metal wiring layer 250. The first through third insulating layers 230, 240, and 260 respectively include openings 235, 245, and 265. In addition, a coating layer 280 is coated on a rear surface 212 of the wafer 210. According to the conventional wafer level package 200, the coating layer 280 is formed on the rear surface 212 of the wafer 210 to prevent the wafer from being damaged due to external shock. However, since the coating layer 280 is formed by coating a resin, it is not strong enough. Therefore, the wafer can still be damaged by external shock.

### SUMMARY OF THE INVENTION

The present invention provides a semiconductor wafer that prevents a semiconductor chip from being damaged and edge clipping from occurring due to external shocks by molding a rear surface of the semiconductor chip.

The present invention also provides a method of fabricating a semiconductor package capable of withstanding external shock by molding a rear surface of a semiconductor chip with semiconductor fabrication process.

According to an aspect of the present invention, there is provided a semiconductor package including: a semiconductor chip including a wafer and a metal pad formed on a front surface of the wafer; a solder ball formed on a front surface of the wafer, and electrically connected to the metal pad; and a reinforcing member formed on a rear surface of the wafer, wherein the reinforcing member is formed of an epoxy molding compound. The reinforcing member may protrude at least 5 μm from the side surfaces of the semiconductor chip. The reinforcing member may protrude about 5˜about 100 μm from the side surfaces of the semiconductor chip. The thickness of the reinforcing member may be about 50˜about 500 μm.

The semiconductor package may further include: a side reinforcing member formed on the protruding portion of the reinforcing member to surround the side surfaces of the semiconductor chip and front edges of the wafer. The side reinforcing member may be one of an epoxy-based resin and a polyimide-based resin.

According to another aspect of the present invention, there is provided a method of fabricating a semiconductor package, the method including: preparing a wafer having a plurality of semiconductor chip regions and a metal pad formed on a front surface of each of the semiconductor chip regions of the wafer; forming a solder ball electrically connected to the metal pad; lapping a rear surface of the wafer to a desired thickness; forming an epoxy molding compound on the lapped rear surface of the wafer; and sawing the wafer to separate the wafer into individual semiconductor chips. The thickness of the epoxy molding compound may be determined according to a lapped thickness of the wafer. The thickness of the epoxy molding compound may be about 50˜about 500 μm.

According to another aspect of the present invention, there is provided a method of fabricating a semiconductor package, the method including: preparing a wafer having a plurality of semiconductor chip regions and a metal pad formed on a front surface of each of the semiconductor chip regions of the wafer; lapping a rear surface of the wafer to a desired thickness; forming an epoxy molding compound on the lapped rear surface of the wafer using a molding process; forming a solder ball electrically connected to the metal pad; and sawing the wafer to separate the wafer into individual semiconductor chips.

According to another aspect of the present invention, there is provided a method of fabricating a semiconductor package, the method including: preparing a wafer having a plurality of semiconductor chip regions and a metal pad formed on a front surface of each of the semiconductor chip regions of the wafer; forming a solder ball electrically connected to the metal pad; lapping a rear surface of the wafer to a desired thickness; forming an epoxy molding compound on the lapped rear surface of the wafer using a molding process; sawing the wafer at semiconductor chip region borders in a first sawing process so that the epoxy molding compound can support the semiconductor chip regions; filling an insulating resin into recesses formed after the sawing of the wafer so as to cover edges of the semiconductor chip regions; and sawing the insulating resin and the epoxy molding compound to separate the wafer into individual semiconductor chips in a second sawing process, wherein the insulating resin remains on side surfaces of each semiconductor chip.

According to another aspect of the present invention, there is provided a method of fabricating a semiconductor package, the method including: preparing a wafer including a plurality of semiconductor chip regions and a metal pad formed on front surface of each of the semiconductor chip regions of the wafer; lapping a rear surface of the wafer to a desired thickness; molding the lapped rear surface of the wafer to be an epoxy molding compound; forming a solder ball electrically connected to the metal pad; sawing the wafer at semiconductor chip region borders in a first sawing process; filling an insulating resin into recesses formed after the sawing of the wafer so as to cover edges of the semiconductor chip regions; and sawing the insulating resin and the epoxy molding compound to separate the wafer into individual semiconductor chips in a second sawing process, wherein the insulating resin remains on side surfaces of each semiconductor chip.

### BRIEF DESCRIPTION OF THE DRAWINGS

The above and other features and advantages of the present invention will become more apparent by describing in detail exemplary embodiments thereof with reference to the attached drawings in which:

FIG. 1 is a cross-sectional view of a wafer level package according to the conventional art;

FIG. 2 is a cross-sectional view of a wafer level package, in which a rear surface of a semiconductor chip is coated, according to the conventional art;

FIG. 3A is a cross-sectional view of a wafer level package, in which a rear surface of a semiconductor chip is molded, according to an embodiment of the present invention;

FIG. 3B is a plan view of the wafer level package, in which the rear surface of the semiconductor chip is molded, of FIG. 3A;

FIG. 4A is a cross-sectional view of a wafer level package, in which a rear surface of a semiconductor chip is molded, according to another embodiment of the present invention;

FIG. 4B is a plan view of the wafer level package, in which the rear surface of the semiconductor chip is molded, of FIG. 4A;

FIG. 5A is a cross-sectional view of a wafer level package, in which a rear surface of a semiconductor chip is molded, according to another embodiment of the present invention;

FIG. 5B is a plan view of the wafer level package, in which the rear surface of the semiconductor chip is molded, of FIG. 5A;

FIGS. 6A through 6F are cross-sectional views for illustrating a method of fabricating a wafer level package according to an embodiment of the present invention;

FIGS. 7A through 7D are cross-sectional views for illustrating a method of fabricating a wafer level package according to an embodiment of the present invention;

FIGS. 8A through 8F are cross-sectional views for illustrating a method of fabricating a wafer level package according to another embodiment of the present invention;

FIGS. 9A through 9D are cross-sectional views for illustrating a method of fabricating a wafer level package according to another embodiment of the present invention;

FIGS. 10A through 10I are cross-sectional views for illustrating a method of fabricating a wafer level package according to another embodiment of the present invention; and

FIGS. 11A through 11D are cross-sectional views for illustrating a method of fabricating a wafer level package according to another embodiment of the present invention.

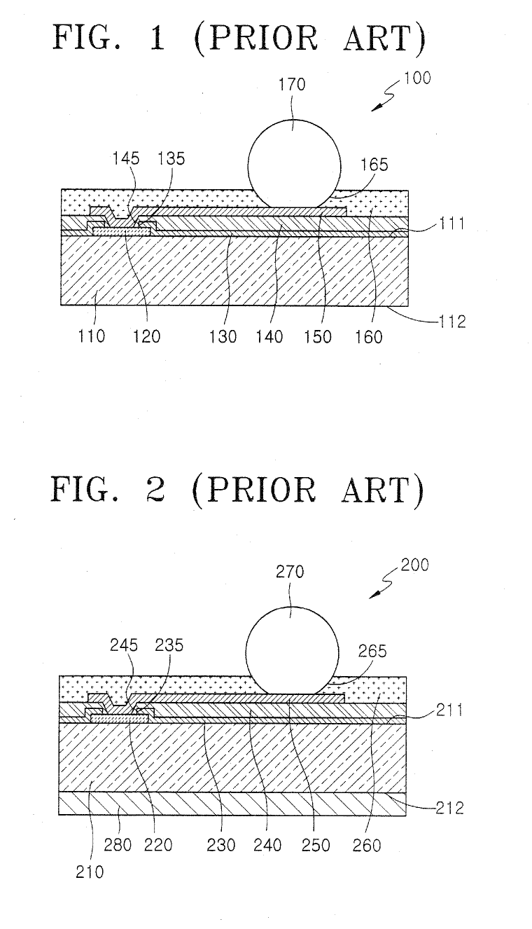

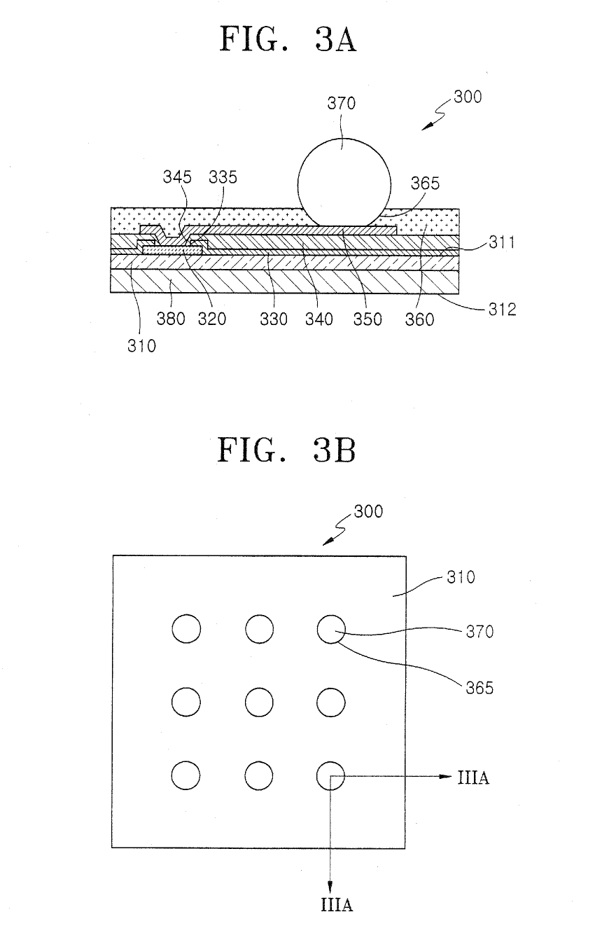

### DETAILED DESCRIPTION OF THE INVENTION

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art. In the drawings, the thicknesses of layers and regions are exaggerated for clarity. Like reference numerals in the drawings denote like elements, and thus their description will be omitted.

FIG. 3A is a cross-sectional view of a wafer level package 300 according to an embodiment of the present invention, and FIG. 3B is a plan view of the wafer level package 300, in which a rear surface of the semiconductor chip is molded, of FIG. 3A. FIG. 3A is a cross-sectional view of the wafer level package 300 taken along line IIIA-IIIA of FIG. 3B. Referring to FIGS. 3A and 3B, the wafer level package 300 includes a semiconductor chip. The semiconductor chip includes a wafer 310, and a metal pad 320 formed on a front surface 311 of the wafer 310. The front surface 311 of the wafer is a surface, to which semiconductor chips including various semiconductor devices (not shown in the drawings) are integrated through semiconductor fabrication processes. The metal pad 320 formed on the front surface 311 of the wafer 310 electrically connects the semiconductor device to the outside, and, may be formed of aluminum.

A first insulating layer 330 is formed on the front surface 311 of the wafer 310, and the first insulating layer 330 includes a first opening 335 exposing a part of the metal pad 320. The first insulating layer 330 is a passivation layer formed of, for example, SiO₂, Si₃N₄, or phospho silicate glass. A second insulating layer 340 is formed on the first insulating layer 330, and the second insulating layer 340 includes a second opening 345 exposing a part of the metal pad 320. The second insulating layer 340 is an interlayer dielectric formed of a polymer-based insulating material.

A metal wiring layer 350 that is connected to the metal pad 320 through the second opening 345 is formed on the second insulating layer 340. The metal wiring layer 350 may be a metal layer such as a copper, and a nickel layer and a titanium layer may be formed on upper and lower portions of the copper layer. A third insulating layer 360 including a third opening 365 exposing a part of the metal wiring layer 350 is formed on the second insulating layer 340. The third insulating layer 360 is an interlayer dielectric formed of a polymer-based insulating material. A solder ball 370 is formed on the metal wiring layer 350 exposed by the third opening 365. The solder ball 370 is electrically connected to the metal pad 320 through the metal wiring layer 350.

The wafer level package 300 further includes an epoxy molding compound 380 on a surface opposing the front surface 311 of the wafer 310, that is, on a rear surface 312. Since the epoxy molding compound 380 having higher strength than that of a resin such as an epoxy resin is used as a reinforcing member, damages generated due to external shock can be prevented and edge cracks can be prevented during a sawing process. A thickness of the epoxy molding compound 380 is dependent on a lapping degree of the wafer 310, and is about 50˜about 500 μm.

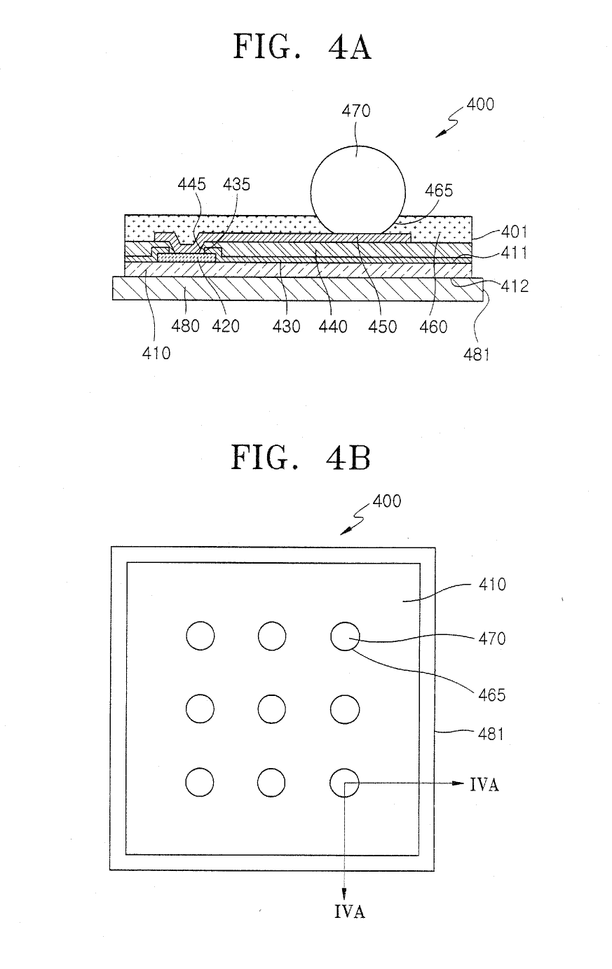

FIG. 4A is a cross-sectional view of a wafer level package 400 according to another embodiment of the present invention, and FIG. 4B is a plan view of the wafer level package 400, in which a rear surface of the semiconductor chip is molded, of FIG. 4A. FIG. 4A is a cross-sectional view of the wafer level package 400 taken along line IVA-IVA of FIG. 4B. Referring to FIGS. 4A and 4B, the wafer level package 400 includes a semiconductor chip. The semiconductor chip includes a wafer 410, and a metal pad 420 formed on a front surface 411 of the wafer 410. The metal pad 420 formed on the front surface 411 of the wafer 410 electrically connects the semiconductor device (not shown in the drawings) to the outside, and may be formed of aluminum.

Like the wafer level package 300 of FIGS. 3A and 3B, a first insulating layer 430, a second insulating layer 440, a metal wiring layer 450, and a third insulating layer 460 are formed on the semiconductor chip. The first insulating layer 430 is formed on the front surface 411 of the wafer 410, and includes a first opening 435 exposing a part of the metal pad 420. The second insulating layer 440 is formed on the first insulating layer 430, and includes a second opening 445 exposing a part of the metal pad 420. The metal wiring layer 450 is formed on the second insulating layer 440, and is connected to the metal pad 420 exposed by the second opening 445. The third insulating layer 460 is formed on the second insulating layer 440, and includes a third opening 465 exposing a part of the metal wiring layer 450. A solder ball 470 is formed on the metal wiring layer 450 exposed by the third opening 465 to be electrically connected to the metal pad 420 through the metal wiring layer 450.

The wafer level package 400 further includes a reinforcing member 480. The reinforcing member 480 is an epoxy molding compound formed on a rear surface 412 of the wafer 410. The reinforcing member 480 includes a protrusion 481 protruding from side surfaces 401 of the semiconductor chip to a predetermined distance. The protrusion 481 of the reinforcing member 480 prevents the edges of the semiconductor chip from being damaged due to external shock, and should protrude at least 5 μm from the side surfaces 401 of the semiconductor chip, for example, 5˜100 μm. A thickness of the reinforcing member 480 is determined according to a lapping degree of the wafer 410, that is, about 50˜about 500 μm. In the wafer level package 400, since the reinforcing member 480 is formed on the rear surface 412 of the wafer 410 and protrudes from the side surfaces 401 of the semiconductor chip 400, damages due to external shock can be prevented.

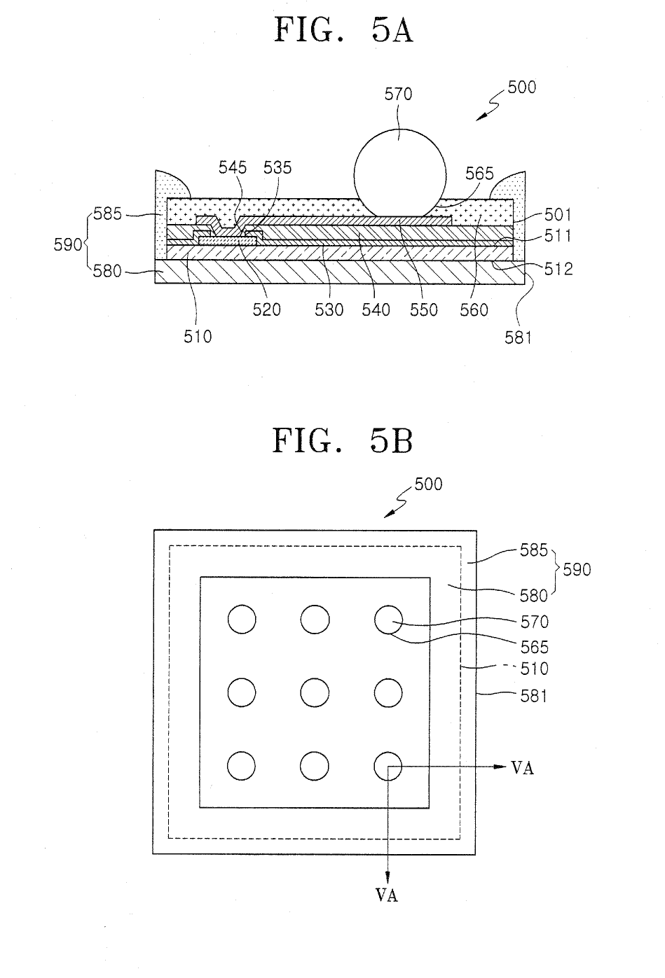

FIG. 5A is a cross-sectional view of a wafer level package 500, in which a rear surface 512 of a semiconductor chip is molded, according to another embodiment of the present invention, and FIG. 5B is a plan view of the wafer level package 500, in which the rear surface 512 of the semiconductor chip is molded, of FIG. 5A. FIG. 5A is a cross-sectional view of the wafer level package taken along line VA-VA of FIG. 5B. Referring to FIGS. 5A and 5B, the wafer level package 500 includes a semiconductor chip. The semiconductor chip includes a wafer 510 and a metal pad 520 formed on a front surface 511 of the wafer 510. The metal pad 520 electrically connects the semiconductor device (not shown in the drawings) formed on the front surface 511 of the wafer 510 to the outside, and may be formed of aluminum.

Like the wafer level package 400 of FIGS. 4A and 4B, the first insulating layer 530 is formed on the front surface 511 of the wafer 510, and includes a first opening 535 exposing a part of the metal pad 520. The second insulating layer 540 is formed on the first insulating layer 530, and includes a second opening 545 exposing a part of the metal pad 520. A metal wiring layer 550 is formed on the second insulating layer 540, and is connected to the metal pad 520 exposed by the second opening 545. A third insulating layer 560 is formed on the second insulating layer 540, and includes a third opening 565 exposing a part of the metal wiring layer 550. A solder ball 570 is formed on the metal wiring layer 550 exposed by the third opening 565 to be electrically connected to the metal pad 520 through the metal wiring layer 550.

The wafer level package 500 further includes a reinforcing member 590. The reinforcing member 590 includes a rear reinforcing member 580 formed on the rear surface 512 of the wafer 510 and a side reinforcing member 585 formed on side surfaces 501 of the semiconductor chip. The rear reinforcing member 580 is an epoxy molding compound formed on the rear surface 512 opposing the front surface 511 of the wafer 510. The rear reinforcing member 580 includes a protrusion 581 protruding from the side surfaces 501 of the semiconductor chip to a predetermined distance. The protrusion 581 protrudes at least 5 μm from the side surfaces 501 of the semiconductor chip, for example, 5˜100 μm. A thickness of the rear reinforcing member 580 is determined according to a lapping degree of the wafer 510, for example, 50˜500 μm. The side reinforcing member 585 is an insulating resin formed on the protrusion 581 of the rear reinforcing member 580 to cover the side surfaces 501 and upper edges of the semiconductor chip. The insulating resin may be an epoxy based resin or a polyimide based resin. Since the rear surface 512 and the side surfaces 501 are supported by the reinforcing member 590, damage to the wafer level package 500 due to external shock can be prevented.

In the embodiments of the present invention, the solder ball is electrically connected to the metal pad through the metal wiring layer of the semiconductor chip, however, the solder ball can be directly connected to the metal pad. Otherwise, the metal wiring layer has a multi-layered structure, and the metal pad and the solder ball are electrically connected to each other through the multi-metal wiring layers.

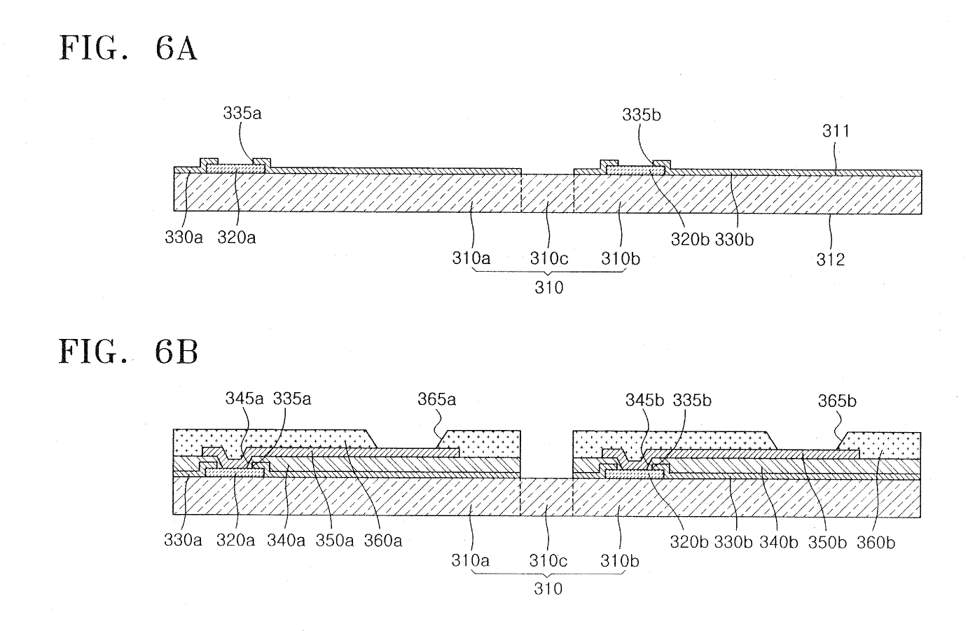

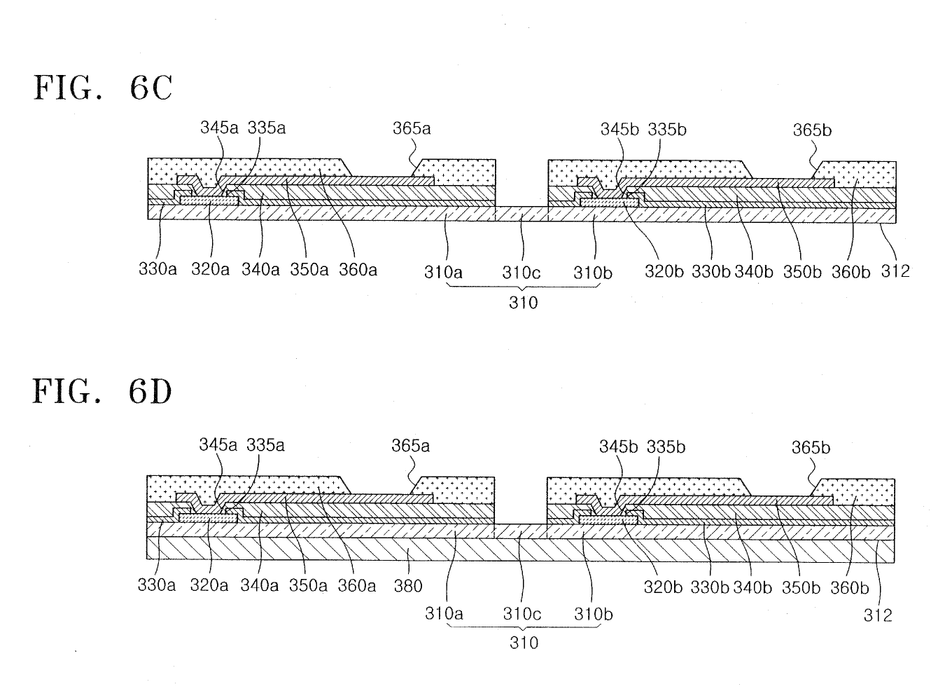

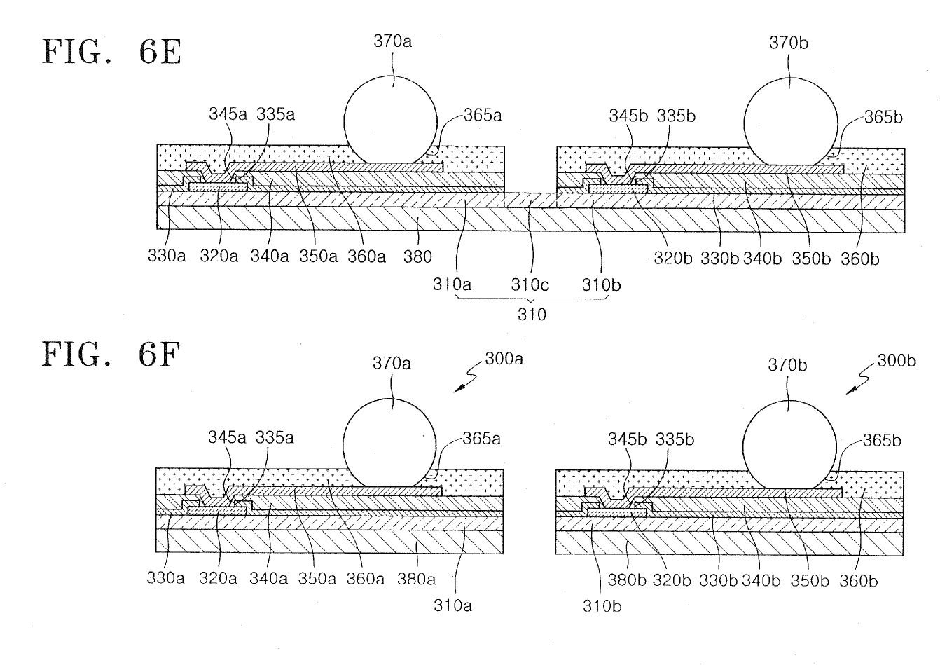

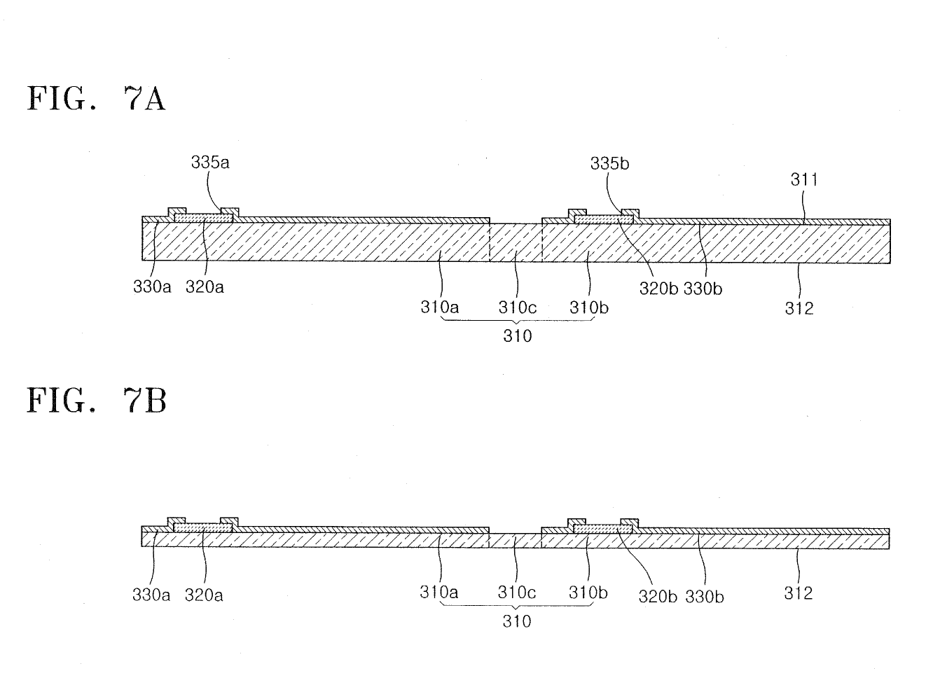

FIGS. 6A through 6F are cross-sectional views for illustrating a method of fabricating a wafer level package according to an embodiment of the present invention. In FIGS. 6A through 6F, two semiconductor chips arranged while interposing a scribe line therebetween are shown. Referring to FIG. 6A, a wafer 310 is provided. A plurality of semiconductor chip regions defined by scribe lines are arranged on the wafer 310. A first semiconductor chip region 310a, in which a first semiconductor chip (300a of FIG. 6F) will be formed, and a second semiconductor chip region 310b, in which a second semiconductor chip (300b of FIG. 6F) will be formed, are arranged while interposing a scribe line 3110c therebetween.

A metal pad 320a and a first insulating layer 330a including a first opening 335a exposing a part of the metal pad 320a are formed on a front surface 311 of the wafer 310 in the first semiconductor chip region 310a. A metal pad 320b and a first insulating layer 330b having a first opening 335b exposing a part of the metal pad 320b are formed on the front surface 311 of the wafer 310 in the second semiconductor chip region 311b. The first insulating layers 330a and 330b are passivation layers, which are formed by depositing SiO₂, Si₃N₄, or PSG using a chemical vapor deposition (CVD) process and photo-etching the deposited material.

Referring to FIG. 6B, a polymer-based insulating material is deposited on the front surface 311 of the wafer 310, and is photo-etched to form second insulating layers 340a and 340b on the first and second semiconductor chip regions 310a and 310b. The second insulating layers 340a and 340b are interlayer dielectrics. The second insulating layer 340a is formed on the first insulating layer 330a of the first semiconductor chip region 310a, and includes a second opening 345a exposing a part of the metal pad 320a that is exposed by the first opening 335a. In addition, the second insulating layer 340b is formed on the first insulating layer 330b of the second semiconductor chip region 310b, and includes a second opening 345b exposing a part of the metal pad 320b that is exposed by the first opening 335b.

In addition, a metal wiring layer 350a electrically connected to the metal pad 320a exposed by the second opening 345a is formed on the second insulating layer 340a of the first semiconductor chip region 310a. In addition, a metal wiring layer 350b electrically connected to the metal pad 320b exposed by the second opening 345b is formed on the second insulating layer 340b of the second semiconductor chip region 310b. The metal wiring layers 350a and 350b may be Cu wiring layers, or Ti/Cu/Ni wiring layers. The metal wiring layers 350a and 350b are formed on the first and second semiconductor chip regions 310a and 310b by depositing a Cu layer using a sputtering process and etching the Cu layer. The metal wiring layers 350a and 350b can be formed by depositing a Ti layer and a Cu layer using a sputtering process and patterning the deposited layers using a photo etching process, and plating a Ni layer on the patterned layer. In addition, the metal wiring layers 350a and 350b can be formed by depositing a Ti layer in a sputtering process, patterning the deposited layer using a photo etching process, and plating a Cu layer and a Ni layer on the patterned layer.

Third insulating layers 360a and 360b are formed on the first and second semiconductor chip regions 310a and 310b by depositing a polymer-based insulating material on the front surface 311 of the wafer 300, and then, photo-etching the deposited layer. The third insulating layers 360a and 360b are interlayer dielectrics. The third insulating layer 360a is formed on the second insulating layer 340a of the first semiconductor chip region 310a, and includes a third opening 365a exposing a part of the metal wiring layer 350a. In addition, the third insulating layer 360b is formed on the second insulating layer 340b of the second semiconductor chip region 310b, and includes a third opening 365b exposing a part of the metal wiring layer 350b.

Referring to FIG. 6C, a rear surface 312 of the wafer 310 is processed using a backlapping process to make the wafer 310 thin. Referring to FIG. 6D, a reinforcing member 380 is formed on the rear surface 312 of the wafer 310. The reinforcing member 380 is formed by forming an epoxy molding compound on the rear surface 312 of the wafer 310. A thickness of the reinforcing member 380 is about 50˜about 500 μm.

The thickness of the reinforcing member 380 is determined in consideration of a desired thickness of the semiconductor package and a lapping degree of the wafer 310, and can be determined according to a content of filler in the epoxy molding compound and a flowing property of the epoxy molding compound. The reinforcing member 380 can be formed by molding the rear surface 312 of the wafer 310 to a desired thickness, or forming the epoxy molding compound to be thicker than the desired thickness on the rear surface 312 and lapping the epoxy molding compound to the desired thickness.

Referring to FIG. 6E, a solder ball 370a is attached onto the metal wiring layer 350a that is exposed by the third opening 365a of the first semiconductor chip region 310a, and a solder ball 370b is attached onto the metal wiring layer 350b that is exposed by the third opening 365b of the first semiconductor chip region 310b. Therefore, the solder ball 370a of the second semiconductor chip region 310a is electrically connected to the metal pad 320a through the metal wiring layer 350a, and the solder ball 370b of the first semiconductor chip region 310b is electrically connected to the metal pad 320b through the metal wiring layer 350b.

Referring to FIG. 6F, the wafer 310 is cut along the scribe line 310c to divide the wafer 310 into a first semiconductor chip 300a and a second semiconductor chip 300b. The cutting process is performed using a saw blade or a laser. Therefore, a package having the same structure as that of the package 300 shown in FIGS. 3A and 3B can be fabricated.

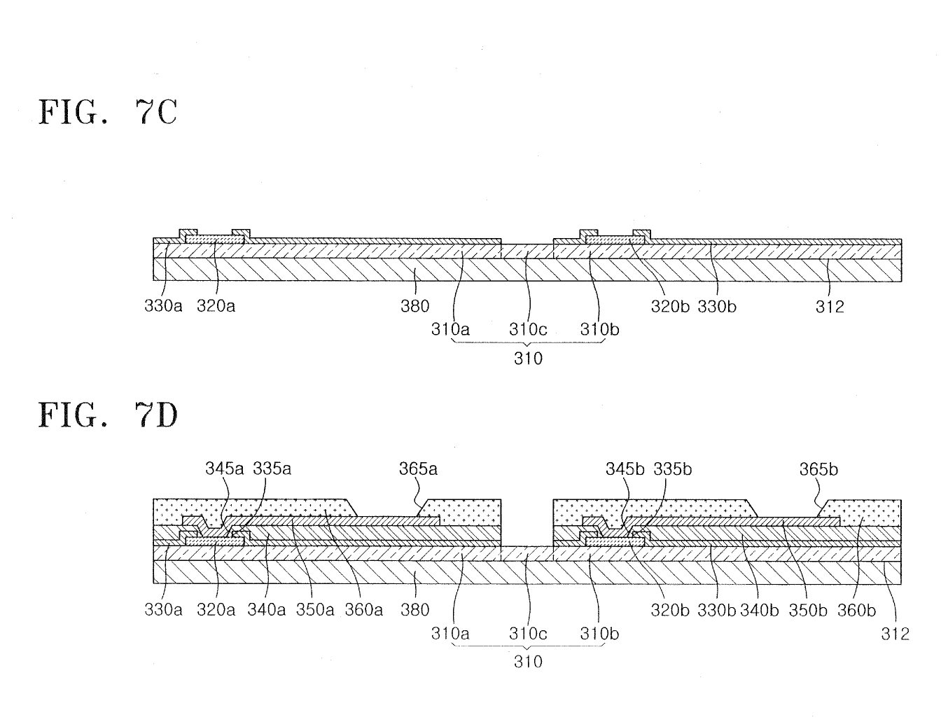

FIGS. 7A through 7D are cross-sectional views for illustrating a method of fabricating the wafer level package of FIGS. 3A and 3B according to an embodiment of the present invention. In FIGS. 7A through 7D, two semiconductor chips among a plurality of semiconductor chip regions defined by scribe lines are illustrated. Referring to FIG. 7A, a wafer 310 includes a plurality of semiconductor chip regions defined by a scribe line 310c. The wafer 310 includes a first semiconductor chip region 310a, in which a first semiconductor chip (300a of FIG. 6F) will be formed, and a second semiconductor chip region 310b, in which a second semiconductor chip (300b of FIG. 6F) will be formed. In addition, the scribe line 310c is disposed between the first semiconductor chip region 310a and the second semiconductor chip region 310b. A metal pad 320a and a first insulating layer 330a including a first opening 335a exposing a part of the metal pad 320a are formed on a front surface 311 of the wafer 310 on the first semiconductor chip region 310a. A metal pad 320b and a first insulating layer 330b having a first opening 335b exposing a part of the metal pad 320b are formed on the front surface 311 of the wafer 310 in the second semiconductor chip region 310b.

Referring to FIG. 7B, a rear surface 312 of the wafer 310 is processed using a backlapping process. Referring to FIG. 7C, a reinforcing member 380 is formed on the rear surface 312 of the wafer 310 by molding the rear surface 312 of the wafer 310 to an epoxy molding compound. The thickness of the reinforcing member 380 is about 50 μm˜about 500 μm. The reinforcing member 380 can be formed by molding the rear surface 312 of the wafer 310 to a desired thickness, or forming the epoxy molding compound to be thicker than the desired thickness on the rear surface 312 and lapping the epoxy molding compound to the desired thickness.

Referring to FIG. 7D, when the reinforcing member 380 is formed on the rear surface 312 of the wafer 310, second insulating layers 340a and 340b respectively including second openings 345a and 345b, metal wiring layers 350a and 350b, and third insulating layers 360a and 360b respectively including third openings 365a and 365b are sequentially formed on the front surface 311 of the wafer 310 on the first and second semiconductor chip regions 310a and 310b. After that, processes of attaching the solder balls 370a and 370b and sawing the wafer 310 to divide the wafer 310 into the first semiconductor chip 300a and the second semiconductor chip 300b are the same as those of FIGS. 6E and 6F.

According to the current embodiment of the present invention, illustrated in FIGS. 7A through 7D, the wafer 310 is lapped to form the reinforcing member 380, and then, the package patterns are formed, and thus, the process can be used to fabricate ultra-thin packages.

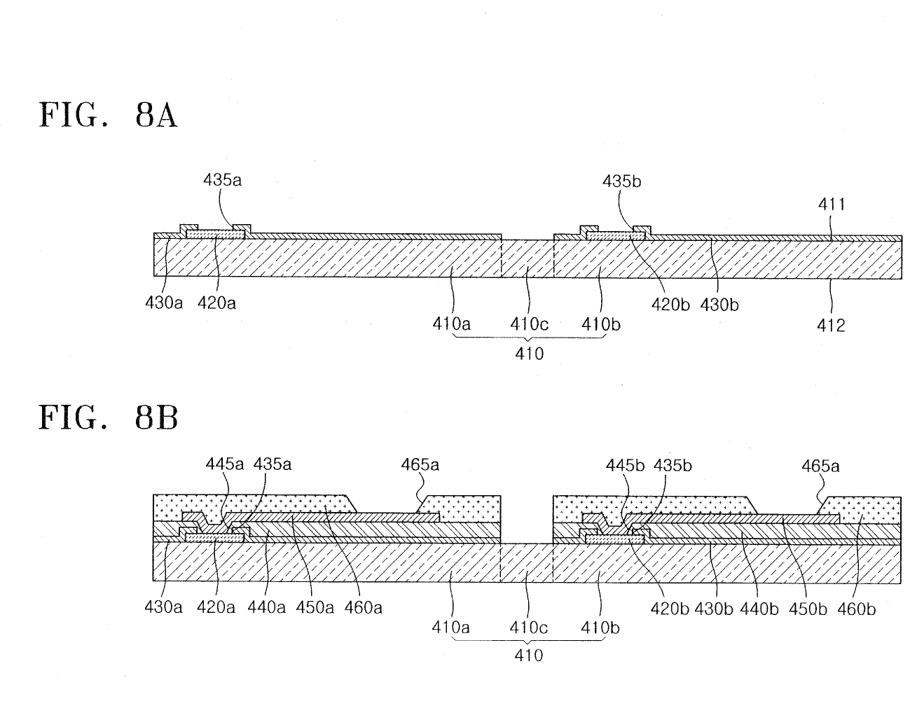

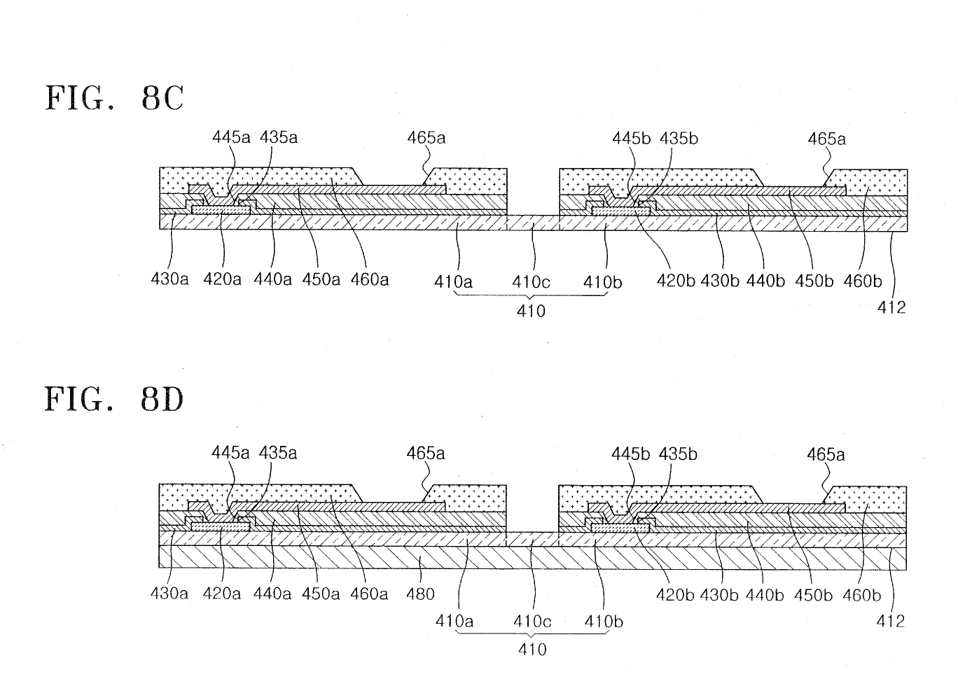

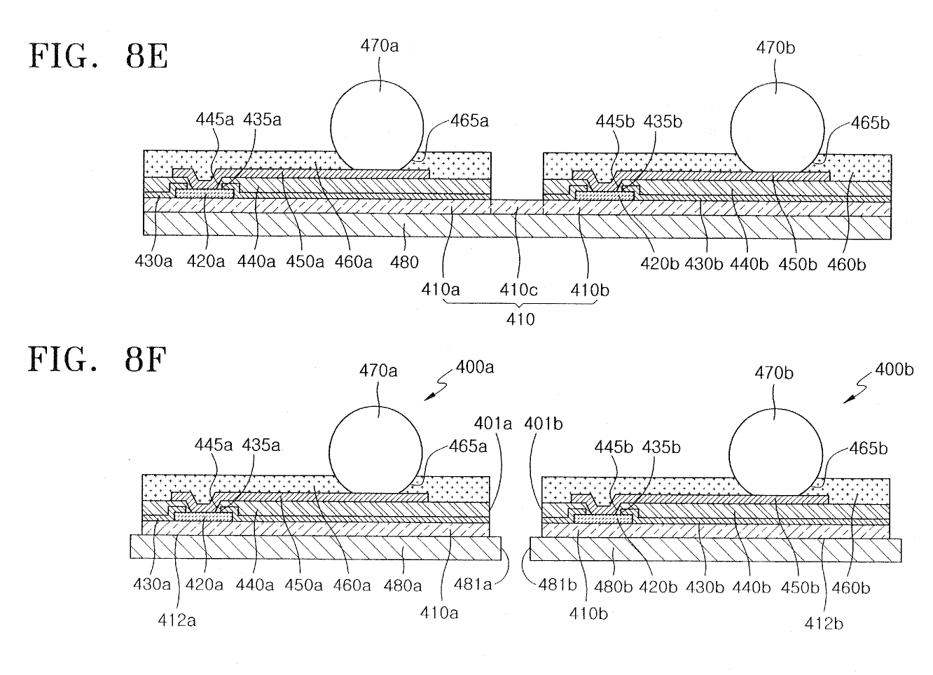

FIGS. 8A through 8F are cross-sectional views illustrating a method of fabricating a wafer level package according to another embodiment of the present invention. In FIGS. 8A through 8F, two semiconductor chips arranged while interposing a scribe line therebetween are illustrated. Processes of forming metal pads 420a and 420b on a first semiconductor chip region 410a and a second semiconductor chip region 410b up to a process of forming solder balls 470a and 470b illustrated in FIGS. 8A through 8E are the same as those of FIGS. 6A through 6E.

A metal pad 420a and a first insulating layer 430a having a first opening 435a exposing a part of the metal pad 420a are formed on a front surface 411 of the wafer 410 in the first semiconductor chip region 410a. A second insulating layer 440a having a second opening 445a exposing a part of the metal pad 420a is formed on the first insulating layer 430a. In addition, a metal wiring layer 450a connected to the metal pad 420a through the second opening 445a is formed on the second insulating layer 440a. A third insulating layer 460a having a third opening 465a exposing a part of the metal wiring layer 450a is formed on the second insulating layer 440a. A solder ball 470a is attached to the metal wiring layer 450a that is exposed by the third opening 465a, and thus, the metal pad 420a and the solder ball 470a are electrically connected to each other through the metal wiring layer 450a.

In addition, a metal pad 420b and a first insulating layer 430b having a first opening 435b exposing a part of the metal pad 420b are formed on the front surface 411 of the wafer 410 in the second semiconductor chip region 410b. A second insulating layer 440b having a second opening 445b exposing a part of the metal pad 420b is formed on the first insulating layer 430b. In addition, a metal wiring layer 450b connected to the metal pad 420b through the second opening 445b is formed on the second insulating layer 440b. A third insulating layer 460b having a third opening 465b exposing a part of the metal wiring layer 450b is formed on the second insulating layer 440b. A solder ball 470b is attached to the metal wiring layer 450b that is exposed by the third opening 465b, and thus, the metal pad 420b and the solder ball 470b are electrically connected to each other through the metal wiring layer 450b.

An epoxy molding compound is formed on a rear surface 412 of the wafer 410 as a reinforcing member 480. FIG. 8F illustrates a process of sawing the wafer 410 into separate semiconductor chips. Referring to FIG. 8F, the wafer 410 having the reinforcing member 480 on the rear surface 412 thereof is sawed along the scribe line 410c to be divided into a first semiconductor chip 400a and a second semiconductor chip 400b. The sawing process is performed two times. First, the wafer 410 is sawed along the scribe line 410c. Since the reinforcing member 480 is formed on the rear surface 412 of the wafer 410 to support the semiconductor chip, the shape of the wafer can be maintained. Next, the exposed reinforcing member 480 is cut to separate the wafer 410 into the first and second semiconductor chips 400a and 400b. Therefore, packages having the same structure as that of the wafer level package 400 illustrated in FIGS. 4A and 4B can be fabricated.

The wafer 410 can be sawed using a saw blade or a laser, and a cutting width of the wafer 410 can be as wide as possible, for example, the width of the scribe line 410c. A cutting width of the reinforcing member 480 is less than the width of the scribe line 410c, and the reinforcing member 480 is cut using a laser. A reinforcing member 480a is formed on a rear surface 412a of the first semiconductor chip 400a, and protrudes a predetermined distance from side surfaces 401a of the first semiconductor chip 400a. In addition, a reinforcing member 480b is formed on a rear surface 412b of the first semiconductor chip 400b, and protrudes a predetermined distance from side surfaces 401b of the first semiconductor chip 400b.

A protrusion 481a of the reinforcing member 480a formed on the first semiconductor chip 400a protrudes at least 5 μm or more from the side surfaces 401a of the first semiconductor chip 400a, and a protrusion 481b of the reinforcing member 480b formed on the first semiconductor chip 400b protrudes at least 5 μm or more from the side surfaces 401b of the first semiconductor chip 400b. Widths of the protrusions 481a and 481b are determined by the width of the scribe line 410c, and may be 5˜100 μm, for example.

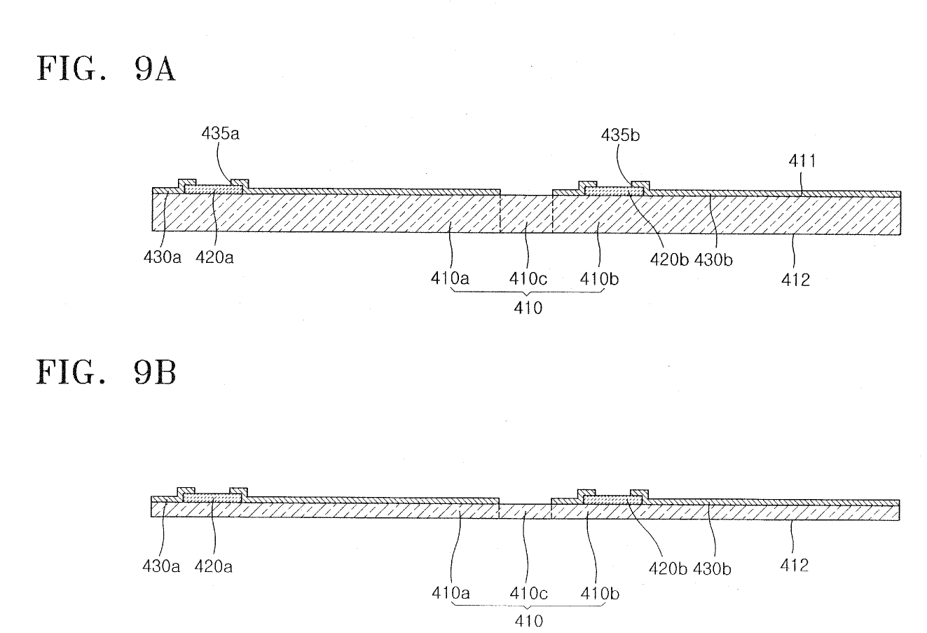

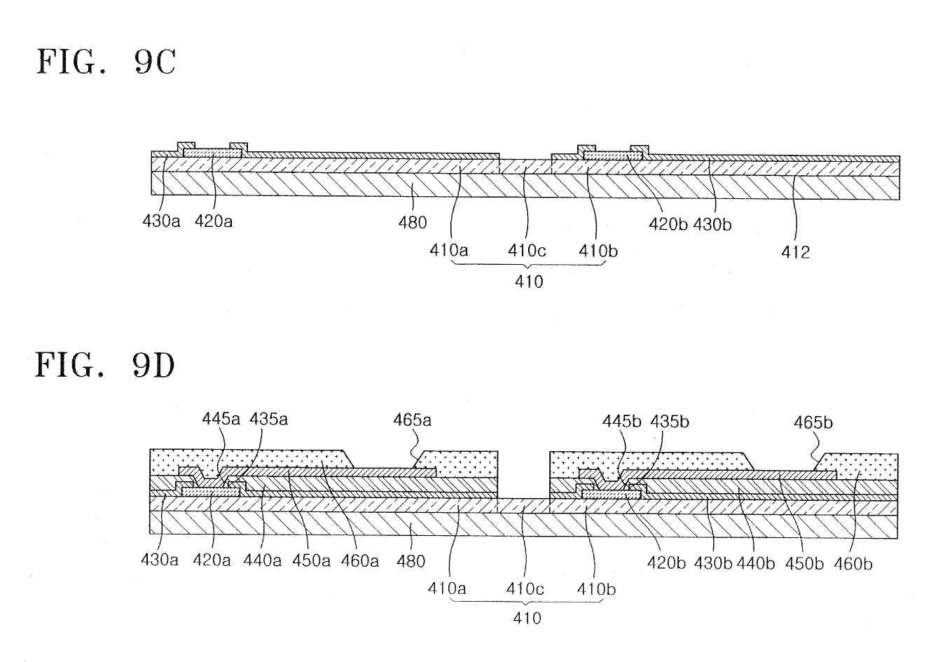

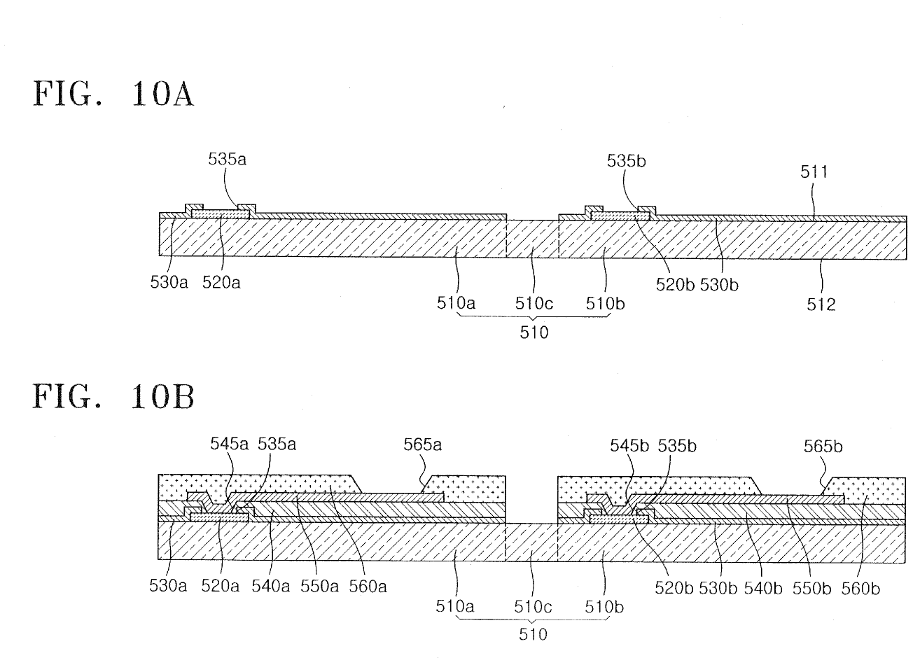

FIGS. 9A through 9D are cross-sectional views illustrating a method of fabricating a wafer level package according to another embodiment of the present invention. In FIGS. 9A through 9D, two semiconductor chip regions among a plurality of semiconductor chip regions arranged on the wafer are illustrated. According to the current embodiment of the present invention, illustrated in FIGS. 9A through 9D, since a reinforcing member is formed before forming package patterns, ultra-thin packages can be fabricated.

Referring to FIG. 9A, a wafer 410 includes a first semiconductor chip region 410a, on which a first semiconductor chip (400a of FIG. 8F) will be formed, and a second semiconductor chip region 410b, on which a second semiconductor chip (400b of FIG. 8F) will be formed. In addition, a scribe line 410c is arranged between the first and second semiconductor chip regions 410a and 410b. A metal pad 420a and a first insulating layer 430a are formed on a front surface 411 of the wafer 410 on the first semiconductor chip region 410a, and a metal pad 420b and a first insulating layer 430b are formed on the front surface 411 of the wafer 410 on the second semiconductor chip region 410b.

Referring to FIG. 9B, a rear surface 412 of the wafer 410 is lapped to a predetermined thickness. Referring to FIG. 9C, an epoxy molding compound is formed on the rear surface 412 of the wafer 410 to form a reinforcing member 480. A thickness of the reinforcing member 480 is determined according to the lapping degree of the wafer, and may be 50˜500 μm. The reinforcing member 480 can be formed to the desired thickness after forming the thick epoxy molding compound and lapping the epoxy molding compound.

Referring to FIG. 9D, when the reinforcing member 480 is formed on the rear surface 412 of the wafer 410, second insulating layers 440a and 440b respectively having second openings 445a and 445b, metal wiring layers 450a and 450b, and third insulating layers 460a and 460b respectively including third openings 465a and 465b are sequentially formed on the front surface 411 of the wafer 410 on the first and second semiconductor chip regions 400a and 400b. After that, processes of attaching the solder ball and sawing the wafer 410 are performed in the same way as those of FIGS. 8E and 8F to fabricate packages having the same structure as that of the wafer level package 400 of FIGS. 4A and 4B.

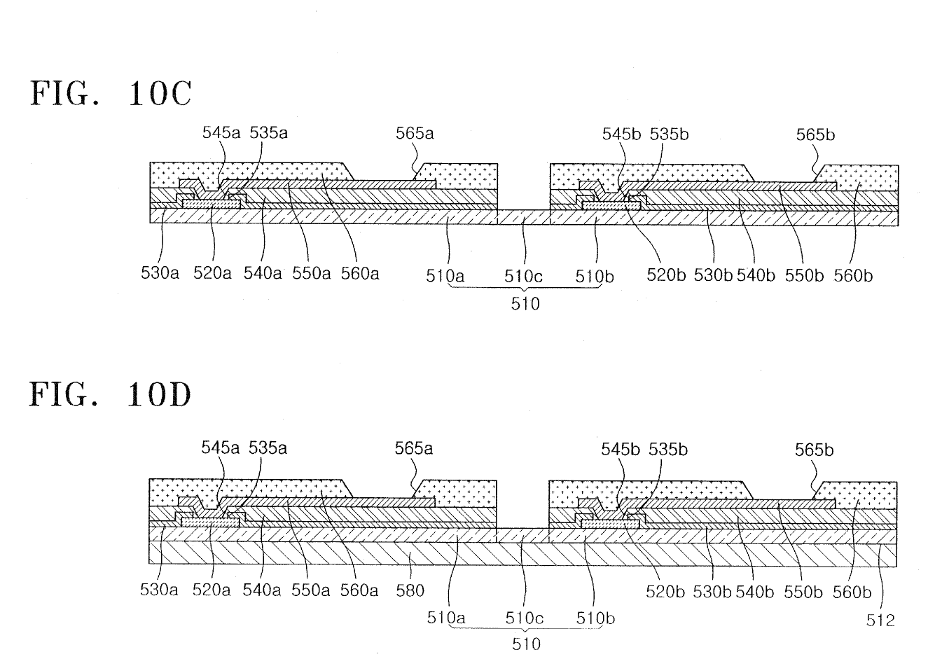

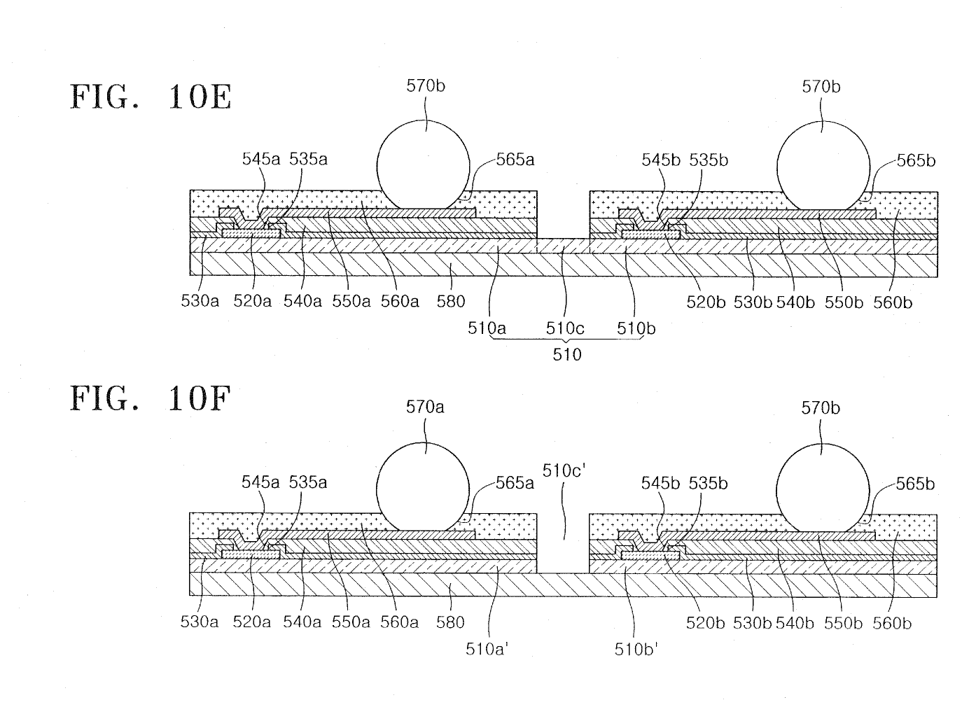

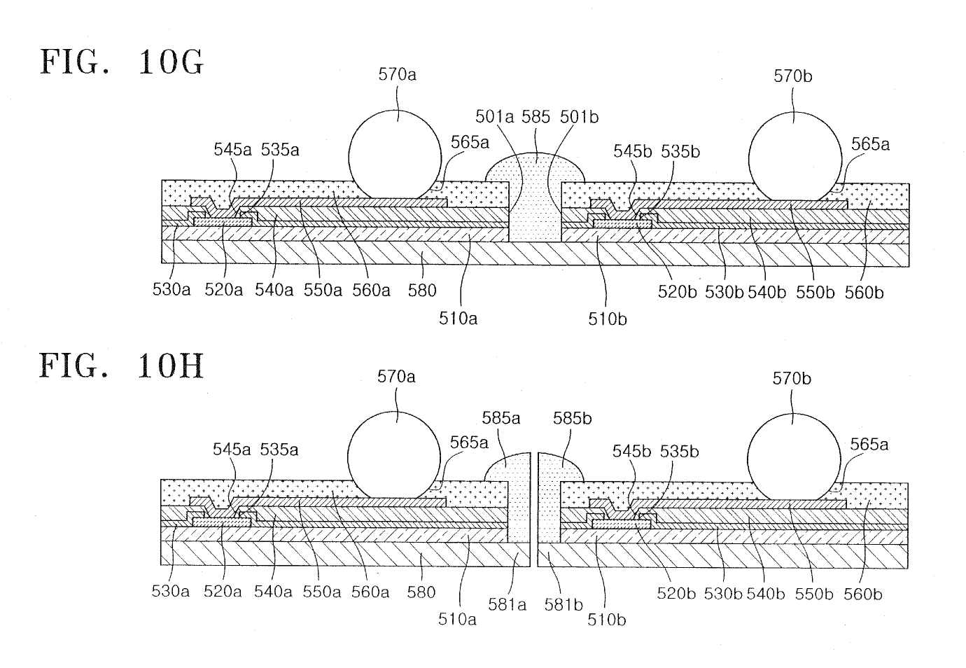

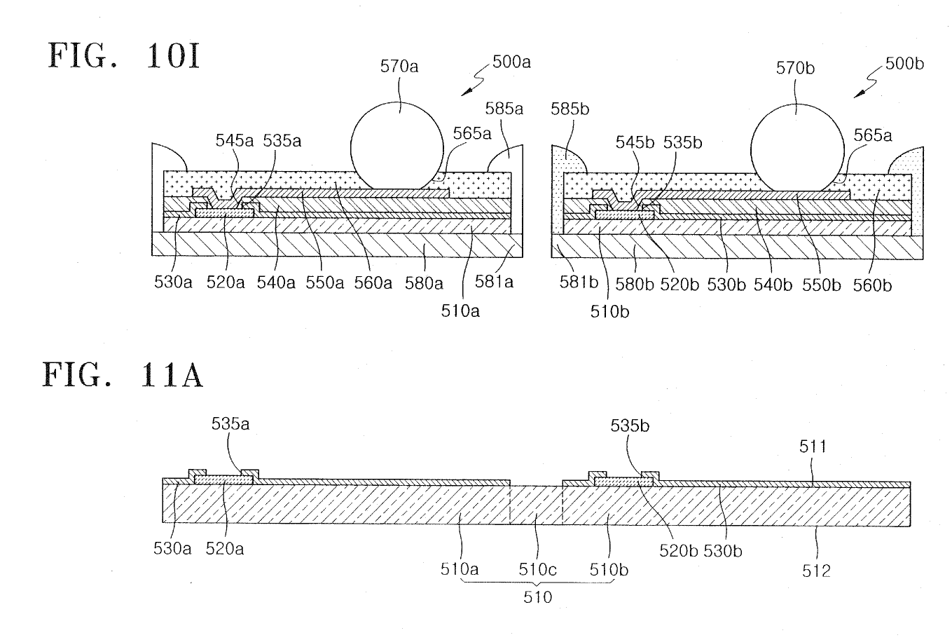

FIGS. 10A through 10I are cross-sectional views illustrating a method of fabricating a wafer level package according to another embodiment of the present invention. In FIGS. 10A through 10I, two semiconductor chip regions among a plurality of semiconductor chip regions arranged on a wafer 510 are illustrated. Processes of forming metal pads 520a and 520b on a first semiconductor chip region 510a and a second semiconductor chip region 510b, up to a process of forming solder balls 570a and 570b of FIGS. 10A through 10E are the same as those of FIGS. 6A through 6E.

A metal pad 520a and a first insulating layer 530a having a first opening 535a exposing a part of the metal pad 520a are formed on a front surface 511 of the wafer 510 in the first semiconductor chip region 510a. A second insulating layer 540a having a second opening 545a exposing a part of the metal pad 520a is formed on the first insulating layer 530a. In addition, a metal wiring layer 550a connected to the metal pad 520a through the second opening 545a is formed on the second insulating layer 540a. A third insulating layer 560a having a third opening 565a exposing a part of the metal wiring layer 550a is formed on the second insulating layer 540a. A solder ball 570a is attached to the metal wiring layer 550a that is exposed by the third opening 565a, and thus, the metal pad 520a and the solder ball 570a are electrically connected to each other through the metal wiring layer 550a.

In addition, a metal pad 520b and a first insulating layer 530b having a first opening 535b exposing a part of the metal pad 520b are formed on a front surface 511 of the wafer 510 in the second semiconductor chip region 510b. A second insulating layer 540b having a second opening 545b exposing a part of the metal pad 520b is formed on the first insulating layer 530b. In addition, a metal wiring layer 550b connected to the metal pad 520b through the second opening 545b is formed on the second insulating layer 540b. A third insulating layer 560b having a third opening 565b exposing a part of the metal wiring layer 450b is formed on the second insulating layer 540b. A solder ball 570b is attached to the metal wiring layer 550b that is exposed by the third opening 565b, and thus, the metal pad 520b and the solder ball 570b are electrically connected to each other through the metal wiring layer 550b.

An epoxy molding compound 580 is formed on a rear surface 512 of the wafer 510. Referring to FIG. 10F, the wafer 510 is sawed along a scribe line 510c through a first sawing process. Since the epoxy molding compound 580 is formed on the rear surface 512 of the wafer 510, the shape of the wafer 510 can be maintained. A recess 510c′ is formed along peripheral portions of the first and second semiconductor chip regions 510a and 510b, and the epoxy molding compound 580 is exposed by the recess 510c′. The wafer 510 is cut using a blade or a laser, and the cutting width of the wafer 510 is the same as a width of the scribe line 510c.

Referring to FIG. 10G, an insulating resin 585, for example, an epoxy-based resin or a polyimide-based resin, is filled in the recess 510c′, and then, the insulating resin 585 is cured through a baking process. The insulating resin 585 covers side surfaces 501a and 501b of the semiconductor chips and upper edges of the semiconductor chips.

Referring to FIGS. 10H and 10I, a second sawing process is performed to cut the epoxy molding compound 580 and fabricate a first semiconductor package and a second semiconductor package. The second sawing process has two stages. First, the epoxy molding compound 580 and the insulating resin 585 are cut in a first cutting operation with a first cut width, and then, the epoxy molding compound 580 and the insulating resin 585 are cut in a second cutting operation with a second width greater than the first cut width to produce a first semiconductor chip 500a and a second semiconductor chip 500b. The first cut width can be less than the width of the scribe line 510c, and the second cut width can be greater than the first cut width and less than the width of the scribe line 510c. The second sawing process is performed using a laser. Therefore, packages having the same structure as that of the wafer level package 500 of FIGS. 5A and 5B can be fabricated.

The first semiconductor chip 500a includes a rear reinforcing member 580a including a protrusion 581a protruding from the side surfaces 501a of the first semiconductor chip 500a, and a side reinforcing member 585a formed on the protrusion 581a to surround the side surface 501a and upper edges of the first semiconductor chip 500a. In addition, the second semiconductor chip 500b includes a rear reinforcing member 580b including a protrusion 581b protruding from the side surface 501b of the second semiconductor chip 500b, and a side reinforcing member 585b formed on the protrusion 581b to surround the side surface 501b and upper edges of the first semiconductor chip 500b.

The protrusion 581a of the reinforcing member 580a protrudes at least 5 μm from the side surface 501a of the first semiconductor chip 500a, and the protrusion 581b of the reinforcing member 580b protrudes at least 5 μm from the side surface 501b of the second semiconductor chip 500b. Protruding widths of the protrusions 581a and 581b are determined by the width of the scribe line 510c, that is, the protruding widths of the protrusions 581a and 581b are respectively about 5˜100 μm from the side surfaces 501a and 501b of the first and second semiconductor chips 500a and 500b.

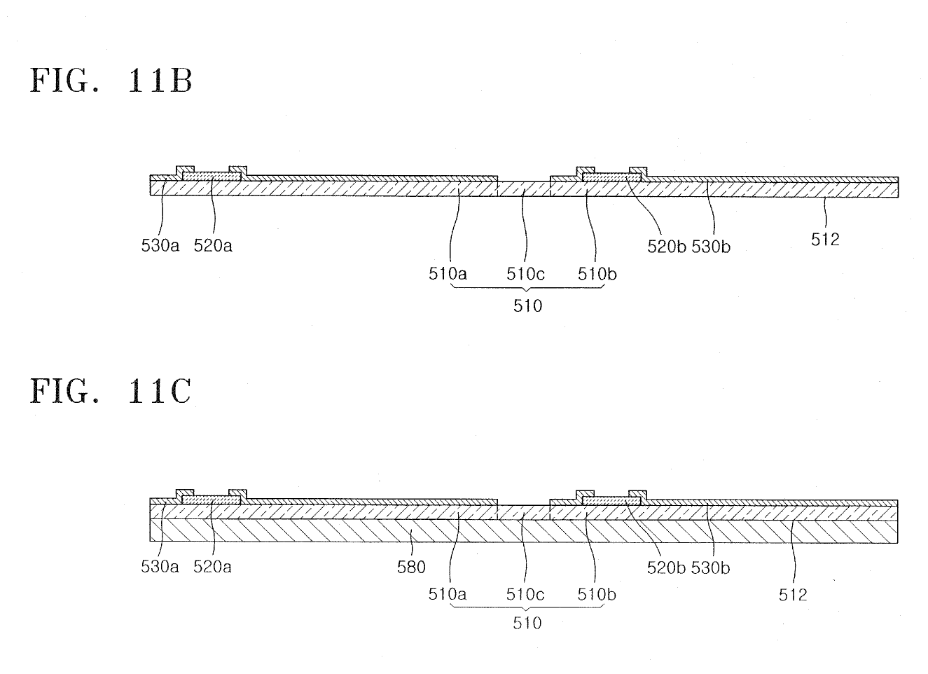

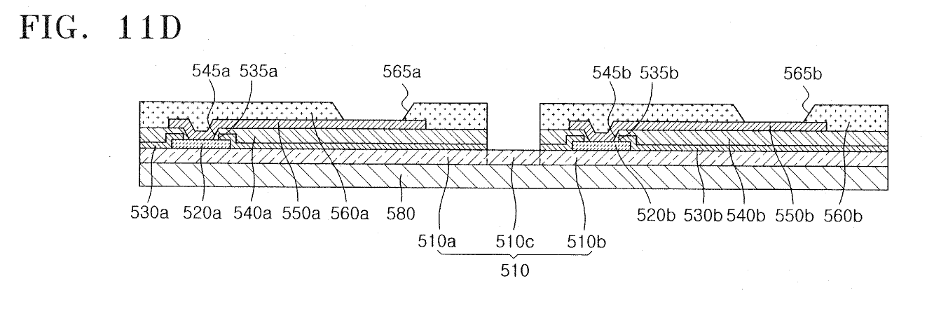

FIGS. 11A through 11D are cross-sectional views for illustrating a method of fabricating a wafer level package according to still another embodiment of the present invention. FIGS. 11A through 11D illustrate two semiconductor chips arranged adjacent to each other while interposing one scribe line therebetween. According to the current embodiment of the present invention, illustrated in FIGS. 11A through 11D, since a reinforcing member is formed before forming package patterns, ultra-thin packages can be fabricated.

Referring to FIG. 11A, a wafer 510 includes a first semiconductor chip region 510a, in which a first semiconductor chip (500a of FIG. 10F) will be formed, and a second semiconductor chip region 510b, in which the second semiconductor chip (500b of FIG. 10F) will be formed. In addition, a scribe line 510c is arranged between the first and second semiconductor chip regions 510a and 510b. A metal pad 520a and a first insulating layer 530a having a first opening 535a are formed on a front surface 511 of the wafer 510 in the first semiconductor chip region 510a, and a metal pad 520b and a first insulating layer 530b having a first opening 535b are formed in the front surface 511 of the wafer 510 on the second semiconductor chip region 510b.

Referring to FIG. 11B, a rear surface 512 of the wafer 510 is lapped to a predetermined thickness. Referring to FIG. 11C, the rear surface 512 of the wafer 510 is molded to an epoxy molding compound to form a reinforcing member 580. A thickness of the reinforcing member 580 can be 50˜500 μm. In addition, the epoxy molding compound 580 can be initially formed to be thicker than a desired thickness, and after that, can be lapped to the desired thickness.

Referring to FIG. 11D, when the reinforcing member 580 is formed on the rear surface 512 of the wafer 510, second insulating layers 540a and 540b respectively having second openings 545a and 545b, metal wiring layers 550a and 550b, and third insulating layers 560a and 560b respectively including third openings 565a and 565b are sequentially formed on the first and second semiconductor chip regions 500a and 500b on the front surface 511 of the wafer 510. After that, processes of attaching a solder ball and sawing the wafer are performed in the same way as those of FIGS. 10E and 10I to fabricate packages having the same structure as that of the wafer level package 500 of FIGS. 5A and 5B.

As described above, according to the present invention, since epoxy molding compound is formed on a rear surface of a semiconductor chip, damage to a wafer level package and warpage of the semiconductor chip due to external shock can be prevented. In addition, when the wafer level package is mounted on a printed circuit board, a mismatching between the package and the circuit board generated due to a coefficient of thermal expansion (CTE) of the semiconductor chip can be reduced and the reliability can be improved.

In addition, according to the present invention, the epoxy molding compound protrudes from side surfaces of the semiconductor chip, and thus, when the semiconductor package is mounted on the printed circuit board, the protrusion can protect the side surfaces of the semiconductor chip and edge clipping of the semiconductor chip can be prevented. Therefore, an additional process for forming a resin protecting the side surfaces of the semiconductor chip is not required.

In addition, in the wafer level package of the present invention, the rear surface of the semiconductor chip is molded using the epoxy molding compound and the side surfaces of the chip are surrounded by the resin, and thus, the edge clipping or the damage generated due to cracks that occurs during performing the sawing process can be prevented.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A semiconductor package comprising:
a semiconductor chip including a wafer and a metal pad formed on a front surface of the wafer;
a solder ball formed on a front surface of the wafer and electrically connectable to the metal pad; and
a reinforcing member formed on a rear surface of the wafer,
wherein the reinforcing member comprises an epoxy molding compound.

2. The semiconductor package of claim 1, wherein the reinforcing member protrudes a given distance from side surfaces of the semiconductor chip.

3. The semiconductor package of claim 2, wherein the reinforcing member protrudes at least about 5 μm from the side surfaces of the semiconductor chip.

4. The semiconductor package of claim 3, wherein the reinforcing member protrudes between about 5 μm and about 100 μm from the side surfaces of the semiconductor chip.

5. The semiconductor package of claim 3, further comprising:
a side reinforcing member formed on the protruding portion of the reinforcing member to surround the side surfaces of the semiconductor chip and at least one edge of the wafer.

6. The semiconductor package of claim 1, wherein the side reinforcing member is one of an epoxy-based resin and a polyimide-based resin.

7. The semiconductor package of claim 1, wherein a thickness of the reinforcing member is determined at least in part with reference to a thickness of the wafer.

8. The semiconductor package of claim 7, wherein the thickness of the reinforcing member is between about 50 μm and about 500 μm.

9. A method of fabricating a semiconductor package, the method comprising:
preparing a wafer having a plurality of semiconductor chip regions and a metal pad formed on a front surface of each of the semiconductor chip regions of the wafer;
forming a solder ball electrically connectable to the metal pad;
forming an epoxy molding compound on a rear surface of the wafer; and
sawing the wafer to separate the wafer into individual semiconductor chips.

10. A method of claim 9, further comprising lapping the rear surface of the wafer to a desired thickness prior to said forming an epoxy molding compound on the rear surface.

11. A method of claim 10, wherein a thickness of the epoxy molding compound is determined at least in part with reference to a lapped thickness of the wafer.

12. A method of claim 11, wherein the thickness of the epoxy molding compound is between about 50 μm and about 500 μm.

13. The method of claim 9, wherein the separation of the wafer into individual semiconductor chips comprises:
first sawing the wafer of semiconductor chip region borders so that the epoxy molding compound can support the semiconductor chips in the first sawing process; and
second sawing the epoxy molding compound corresponding to the semiconductor chip region borders to separate the wafer into the individual semiconductor chips in the second sawing step.

14. The method of claim 13, wherein the epoxy molding compound protrudes from sawed surfaces of the semiconductor chips.

15. The method of claim 14, wherein the epoxy molding compound protrudes approximately 5 μm or more from the sawed surfaces of the semiconductor chips.

16. A method of fabricating a semiconductor package, the method comprising:
preparing a wafer having a plurality of semiconductor chip regions and a metal pad formed on a front surface of each of the semiconductor chip regions of the wafer;
forming an epoxy molding compound on a rear surface of the wafer using a molding process;
forming a solder ball electrically connectable to the metal pad; and
sawing the wafer to separate the wafer into individual semiconductor chips.

17. The method of claim 16, further comprising lapping the rear surface of the wafer to a desired thickness prior to said forming an epoxy molding compound on the rear surface.

18. The method of claim 17, wherein a thickness of the epoxy molding compound is determined at least in part with reference to a lapped thickness of the wafer.

19. The method of claim 18, wherein the thickness of the epoxy molding compound is between about 50 μm and about 500 μm.

20. The method of claim 16, wherein the separation of the wafer into individual semiconductor chips comprises:
first sawing the wafer at semiconductor chip region borders so that the epoxy molding compound can support the semiconductor chips in the first sawing step; and
second sawing the epoxy molding compound corresponding to the sawed portions of the wafer to separate the wafer into the individual semiconductor chips in the second sawing step.

21. The method of claim 20, wherein the epoxy molding compound protrudes from sawed surfaces of the semiconductor chips.

22. The method of claim 21, wherein the epoxy molding compound protrudes approximately 5 μm or more from the sawed surfaces of the semiconductor chips.

23. A method of fabricating a semiconductor package, the method comprising:
preparing a wafer having a plurality of semiconductor chip regions and a metal pad formed on a front surface of each of the semiconductor chip regions of the wafer;
forming a solder ball electrically connectable to the metal pad;
forming an epoxy molding compound on a rear surface of the wafer using a molding process;
first sawing the wafer at semiconductor chip region borders so that the epoxy molding compound can support the semiconductor chip regions;
filling an insulating resin into recesses formed after the sawing of the wafer so as to cover edges of the semiconductor chip regions; and
second sawing the insulating resin and the epoxy molding compound to separate the wafer into individual semiconductor chips, wherein the insulating resin remains on at least one side surface of each semiconductor chip.

24. The method of claim 23, further comprising lapping the rear surface of the wafer to a desired thickness prior to said forming an epoxy molding compound on the rear surface.

25. The method of claim 24, wherein a thickness of the epoxy molding compound is determined according to a lapped thickness of the wafer.

26. The method of claim 25, wherein the thickness of the epoxy molding compound is between about 50 μm and about 500 μm.

27. The method of claim 25, wherein the separation of the wafer into the individual semiconductor chips is performed through a two-stage sawing process.

28. The method of claim 25, wherein the epoxy molding compound protrudes approximately 5 μm or more from sawed surfaces of the semiconductor chips.

29. A method of fabricating a semiconductor package, the method comprising:
preparing a wafer including a plurality of semiconductor chip regions and a metal pad formed on front surface of each of the semiconductor chip regions of the wafer;
molding a rear surface of the wafer to be an epoxy molding compound;
forming a solder ball electrically connectable to the metal pad;
first sawing the wafer at semiconductor chip region borders;
filling an insulating resin into recesses formed after the first sawing step so as to cover edges of the semiconductor chip regions; and
second sawing the insulating resin and the epoxy molding compound to separate the wafer into individual semiconductor chips, wherein the insulating resin remains on side surfaces of each semiconductor chip.

30. The method of claim 29, further comprising lapping the rear surface of the wafer to a desired thickness prior to said forming an epoxy molding compound on the rear surface.

31. The method of claim 30, wherein a thickness of the epoxy molding compound is determined at least in part with reference to a lapped thickness of the wafer.

32. The method of claim 31, wherein the thickness of the epoxy molding compound is between about 50 μm and about 500 μm.

33. The method of claim 29, wherein the separation of the wafer into the individual semiconductor chips is performed through a two-stage sawing process.

34. The method of claim 29, wherein the epoxy molding compound protrudes approximately about 5 μm or more from sawed surfaces of the semiconductor chips.
